(19) United States
(12) Patent Application Publication
(10) Pub. No.: US 2007/0089900 A1
(43) Pub. Date: Apr. 26, 2007

(54) Flexible board

(75) Inventors: Kazuhiro Mitamura, Kawasaki (JP); Junichi Shimizu, Kawasaki (JP); Isao Watanabe, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/585,204

(22) Filed: Oct. 24, 2006

(30) Foreign Application Priority Data
Oct. 26, 2005 (JP) 2005-311483

(51) Int. Cl. H05K 1/00

(52) U.S. Cl. 174/254

(57) ABSTRACT

A flexible board capable of being bent easily and precisely a plurality of times at desired positions has insulating layer exhibiting flexibility, a conductor layer and recessed angular portions situated in both side edges of the board so as to oppose each other. Three of more of these angular portions are disposed on each side edge of the board. More specifically, the flexible board has at least one constricted portion that reduces the width of the board. The constricted portion is situated on both side edges of the board in such a manner that the constricted portions oppose each other, and has at least one of a step portion having a step-like shape and a cut-out portion having a V- or U-like shape. Three or more step-like portions and cut-out portions are situated together on each side edge the board.

### FIELD OF THE INVENTION

This invention relates to a flexible board for electrically connecting components. More particularly, the invention relates to a flexible board that is capable of being bent.

### BACKGROUND OF THE INVENTION

Electronic components that have been developed in recent years have become smaller and more complex. Not only are the components disposed within these devices limited in terms of position and orientation but they also require highly precise mounting. In order to realize a desired layout in such an electronic device, a flexible circuit board exhibiting flexibility and having a metal foil serving as a conductor situated inside or outside a resin film serving as an insulating layer is used as means for electrically interconnecting the components of the electronic device. As examples of uses of a flexible board, FIG. 1 is a schematic view of the interior of an optical transceiver 21, and FIGS. 7A, 7B are plan views of a flexible board according to the prior art. As shown in FIG. 1, the optical transceiver 21 includes a transceiving module 23 having a light-receiving element and a light-emitting element (neither of which are shown) the mounting positions and orientations of which are limited. By way of example, in a case where the positional relationship is such that the connection surface of the transceiving module 23 and the connection surface of a mounting board 25 on which a driving circuit has been mounted are orthogonal, as illustrated in FIG. 1, the module and board are electrically connected using a flexible board 11 of the kind illustrated in FIG. 7A or 7B. The mounting procedure of the flexible board 11 shown in FIG. 1 is illustrated in FIGS. 2A, 2B and 2C. First, at the step illustrated in FIG. 2A, leads 24 of the transceiving module 23 are fitted into connecting portions 12 of the flexible board 11. The leads 24 are then soldered. Next, at the step illustrated in FIG. 2B, the flexible board 11 is bent into a prescribed shape. Then, at the step illustrated in FIG. 2C, the flexible board 11 is mounted on the mounting board 25. At the step of FIG. 2B, the flexible board 11 is bent at points B and C into a substantially U-shaped configuration, and is bent close to 90° at point D. The flexible board 11 is bent at point A as well in such a manner that a strip-off force will not act upon the contacting surfaces of the transceiving module 23 and flexible board 11. The usual flexible board 11 has the form shown in FIG. 7A. However, in another form known in the art, silk-screened lines 15 consisting of an epoxy resin are introduced along the bending lines by a silk screen printing technique in order to indicate the bending positions, as illustrated in FIG. 7B.

Other examples of flexible boards known in the art include a flexible board in which bending positions are provided with rectangular cut-outs to facilitate the bending of the flexible board (see the specification of Japanese Patent Kokai Publication No. JP-P2001-298217A, referred to as “Patent Document 1” below); a printed wiring board provided with a plurality of through-holes at locations of bends devoid of conductor circuits (see the specification of Japanese Patent Kokai Publication No. JP-A-3-257985, referred to as “Patent Document 2” below); a flexible board the bending of which is facilitated by reducing thickness at the bent portions (see the specification of Japanese Patent Kokai Publication No. JP-A-3-112594, referred to as “Patent Document 3” below); a flexible printed circuit board in which conductor patterns are made to include indicia in order to clearly indicate the bending positions (see the specification of Japanese Patent Kokai Publication No. JP-A-4-18785, referred to as “Patent Document 4” below); and a circuit board which, although it is not a flexible board, is formed to have rectangular constrictions to enable the bending of a board formed of a hard material such as glass epoxy resin, and is further formed to have grooves or the like along the bending lines in order to facilitate bending (see the specification of Japanese Patent Kokai Publication No. JP-P2005-191432A, referred to as “Patent Document 5” below).

[Patent Document 1]

Japanese Patent Kokai Publication No. JP-P2001-298217A

[Patent Document 2]

Japanese Patent Kokai Publication No. JP-A-3-257985

[Patent Document 3]

Japanese Patent Kokai Publication No. JP-A-4-112594

[Patent Document 4]

Japanese Patent Kokai Publication No. JP-A-4-18785

[Patent Document 5]

Japanese Patent Kokai Publication No. JP-P2005-191432A

### SUMMARY OF THE DISCLOSURE

A flexible board exhibiting flexibility lacks bendability owing to its restoration force. In particular, if one end of a flexible board is bent after it is joined to an electronic component, the joint is subjected to stress at the time of the bending operation and there is the danger that joinability will suffer. Further, repeating the bending operation because the board is difficult to bend detracts from the efficiency of a parts mounting operation. Furthermore, if a flexible board cannot be maintained in the bent state, it will attempt to return to its original form by spring-back. The bending angle (or radius of curvature), therefore, will be larger than the desired bending angle (or radius of curvature). As a result, the joint between the flexible board and a mounting board (or transceiving module) joined to the flexible board is subjected to a force in a direction that attempts to separate the two boards from each other. The end result is a decline in the connection reliability of the flexible board.

Further, it is necessary for the bending positions of a flexible board to be decided in advance. However, since bending positions are specified one by one in every bending operation, the efficiency of the operation is poor. Although a flexible board with silk-screened lines of the kind shown in FIG. 7B also is available, the silk-screened lines have a fixed width. Consequently, even though the flexible board is bent based upon the silk-screened lines, there is a variance in the bending positions. Furthermore, adding on the step of printing the silk-screened lines on the flexible board is undesirable in terms of manufacturing efficiency and cost.

In an arrangement having a single rectangular cut-out of the kind described in Patent Documents 1 and 2, bending the flexible board upon itself is easy. However, the flexible board is not suitable for being bent precisely a plurality of times in the manner illustrated in FIGS. 1 and 3. With such a flexible board, therefore, various layouts of electronic devices cannot be supported and the flexible board cannot be bent in accurate fashion. In the arrangement having the grooves, as described in Patent Document 3, the grooves must be formed in a flexible board that usually has a thickness of 100 μm or less, and this is undesirable in terms of labor and cost. The arrangement in which conductor patterns have indicia of the kind described in Patent Document 4 is similar to that having the silk-screened lines, and bendability of the flexible board itself cannot be improved. Further, the board described in Patent Document 5 is a hard board such as one of glass epoxy resin. Bendability of a flexible board such as one made of polyimide is not improved.

Accordingly, it is an object of the present invention to provide a flexible board that is capable of being bent easily and precisely a plurality of times at the desired positions.

In the present invention, a flexible board is formed to have a load-bearing portion for causing bending load to concentrate at a bending position, the load-bearing portion serving as means for indicating the bending position. The load-bearing portion preferably has a recessed angular portion so as to enable the flexible board to be bent exactly a plurality of times.

In accordance with a first aspect of the present invention, the flexible board comprises an insulating layer exhibiting flexibility; a conductor layer; and a load-bearing portion that causes bending load to concentrate at a bending position.

In accordance with a second aspect of the present invention, the flexible board comprises an insulating layer exhibiting flexibility; a conductor layer; and recessed angular portions situated in both side edges of the flexible board so as to oppose each other; each side edge of the flexible board having three or more of the angular portions.

In accordance with a third aspect of the present invention, the flexible board comprises an insulating layer exhibiting flexibility; a conductor layer; and at least one constricted portion for reducing width of the flexible board; wherein the constricted portion is situated on both side edges of the flexible board in such a manner that the constricted portions oppose each other, and has at least one of a step portion having a step-like shape and a cut-out portion having a V- or U-like shape; three or more in total of step-like portions and/or cut-out portions being situated together on each side edge of the flexible board.

In accordance with a preferred mode of working the third aspect, one step portion or cut-out portion reduces the width of the flexible board by at least 0.1 mm.

In accordance with preferred modes of working the first to third aspects, the thickness of the flexible board is less than 0.1 mm. In accordance with other preferred modes, the insulating layer is polyimide and the conductor layer is copper. In accordance with other preferred modes, the flexible board is used in an optical transceiver.

The meritorious effects of the present invention are summarized as follows.

In accordance with the present invention, forming the flexible board to have the load-bearing portion (recessed angular portion or constriction) makes it possible to bend the flexible board easily a prescribed number of times at the required positions without dispersing the bending load. Since bending position is defined clear by the load-bearing portion, the efficiency of the bending operation is improved and bending positions can be unified from one flexible board to another. In particular, when the flexible board is bent after one end of the board is joined to an electronic component, as illustrated in FIGS. 2A to 2C, the board can be bent easily and efficiently at the prescribed positions without subjecting the joint to stress. Further, since the bend is assured by the load-bearing portion, the amount of spring-back can be reduced and joinability is improved. Furthermore, the flexible board according to the present invention readily lends itself to the design of electronic components. In other words, by adjusting the number and spacing of the recessed angular portions or the length and width of the constricted portions, namely the number and spacing of step portions and/or cut-out portions, the flexible board can readily be made to support a desired component layout.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a schematic side view illustrating an example of the internal structure of an optical transceiver that uses a flexible board;

FIGS. 2A to 2C are process diagrams illustrating the mounting procedure of a flexible board in the optical transceiver shown in FIG. 1;

FIGS. 3A to 3D are plan views illustrating the form of a flexible board according to the present invention, the board having step portions;

FIGS. 4A to 4C are plan views illustrating the form of a flexible board according to the present invention, the board having cut-outs;

FIGS. 5A to 5C are plan views illustrating another form of a flexible board according to the present invention;

FIG. 6 is a plan view illustrating a flexible board fabricated in a first embodiment; and

FIGS. 7A and 7B are plan views illustrating conventional flexible boards (related art) applied to the optical transceiver shown in FIG. 1.

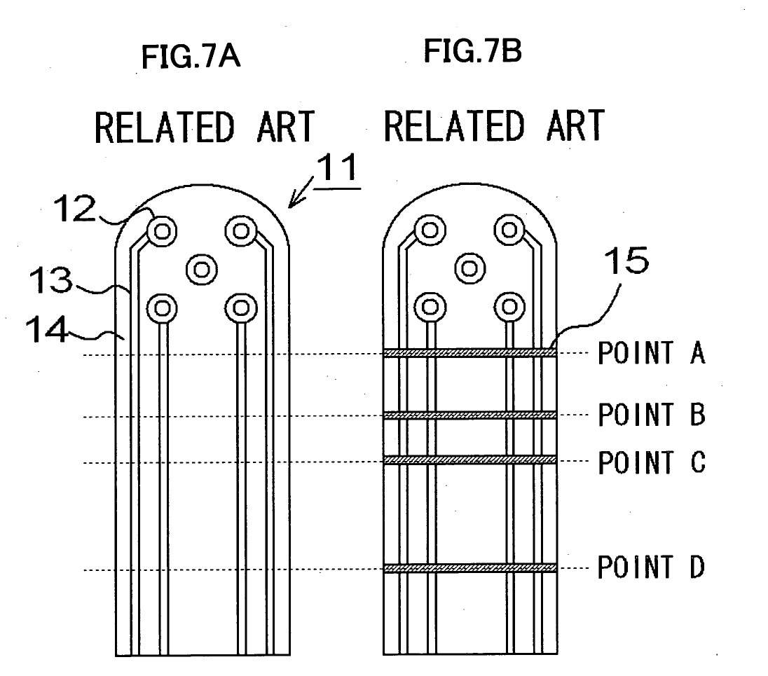

### PREFERRED EMBODIMENTS OF THE INVENTION

The present invention will now be described in detail with reference to the accompanying drawings.

A flexible board has a conductor layer disposed inside or outside an insulating layer that exhibits flexibility and usually is used in electrically interconnecting components. In the flexible board of the present invention, the flexible board is provided with means for concentrating bending load at bending positions (first aspect of the invention) or, preferably, with recessed angular portions at the bending positions (second aspect of the invention). It will suffice if each recessed angular portion has an overall shape in the form of an angular recess. That is, the angular portion may be of a shape having an apex or of a shape having roundness. For example, the angular portion may be a portion formed by straight lines or a portion formed by arcuate curved lines. The recessed angular portions are disposed on both side edges of the flexible board in such a manner that a pair of angular portions is formed with respect to each single bending point. Preferably, three or more recessed angular portions are formed on each side edge of the flexible board (i.e., three or more pairs of the angular portions are formed).

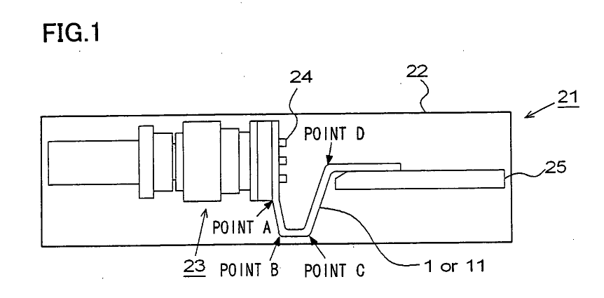

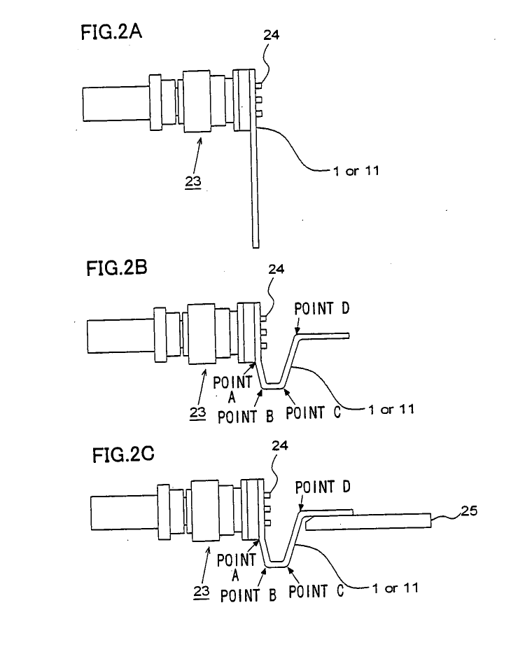

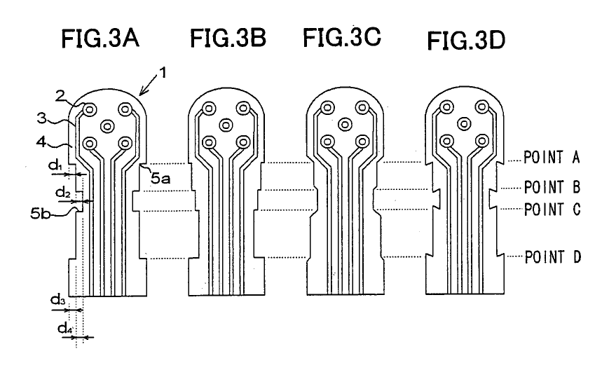

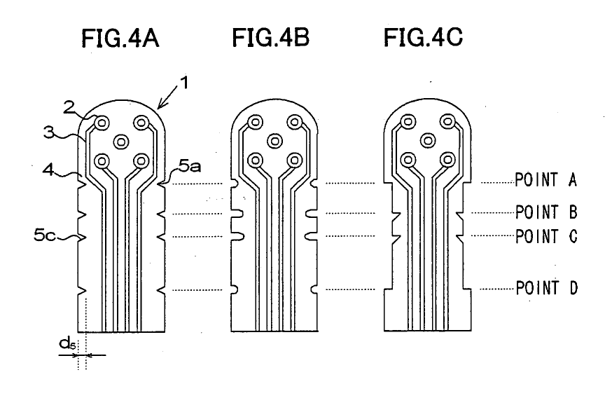

Constricted portions (third aspect) that narrow the width of the flexible board are formed as a more detailed mode of working the second aspect of the invention. The constricted portions are disposed on both side edges of the flexible board so as to oppose each other, and each constriction has a step portion and/or a cut-out portion. A pair of the step portions and/or cut-out portions are formed with respect to each single bending point. Preferably, three or more are formed on each side edge of the flexible board (i.e., three or more pairs are formed). Examples of flexible boards according to the present invention are illustrated in FIGS. 3A to 3D and FIGS. 4A to 4C. FIGS. 3A to 3D are diagrams mainly illustrating flexible boards having step portions, and FIGS. 3A to 3D and FIGS. 4A to 4C. FIGS. 4A to 4C are diagrams mainly illustrating flexible boards having cut-out portions. The forms of the flexible boards illustrated in FIGS. 3A to 3D and FIGS. 4A to 4C each have four bending positions A to D of the kind shown in FIGS. 1 and 2A to 2C.

In the form of the invention shown in FIGS. 3A to 3D, both side edges of a flexible board 1 are formed to include a plurality of step portions 5b that narrow the width of the board. The step portion 5b refers to a single step-like portion (a difference in level). The step portion 5b may be of any shape and may be one in which a recessed angular portion 5a has an apex or roundness. In the form of the invention shown in FIGS. 3A to 3D, the flexible board 1 has four of the step portions 5b on each side edge, and one pair of mutually opposing step portions 5b is formed with respect to each single bending position. Thus, four pairs of the recessed angular portions 5a are formed. By narrowing the width of the flexible board by means of the step portions 5b, the flexible board 1 becomes easy to bend along lines connecting the mutually opposing recessed angular portions 5a that construct the step portions 5b. Accordingly, it is so arranged that the recessed angular portions 5a are placed along the bending points (points A to D).

For example, in the form of the invention illustrated in FIG. 3A, four step portions 5b are formed in such a manner that the narrowest portion of the flexible board 1 will be situated at the intermediate step portions. In the form of the invention illustrated in FIG. 3B, however, the step portions 5b are formed in such a manner that the narrowest portion of the flexible board 1 will be situated at the lowermost step portions. Preferably, the step portions are formed in such a manner that a portion having the largest bending angle or a portion at which it is desired to reduce spring-back will be the narrowest portion of the flexible board. Further, the arrangement is such that the angular portions of the step portions 5b in FIGS. 3A and 3B are 90° or 270°, i.e., such that the lines forming the angular portions are at right angles. In FIGS. 3C and 3D, however, the angles of intersections of the lines forming the angular portions are not right angles. Here the recessed angular portions 5a constituting the bending positions of the board define angles of 180° to 270° in the arrangement illustrated in FIG. 3C and angles of 270° to 360° in the arrangement illustrated in FIG. 3D.

One step portion 5b preferably reduces the width of the flexible board by at least 0.1 mm. For example, in the case of the arrangement shown in FIG. 3A, widths d₁ to d₄ preferably are each at least 0.1 mm and, more preferably, 0.2 mm or greater. The widths d₁ to d₄ can be made different from one another, and it is so arranged that the widths d₁ to d₄ are set appropriately in accordance with the position of a conductor layer 3 and bending angle. In a case where one difference in level of the step portion 5b is expressed by a ratio with respect to the full width of the flexible board 1, it is preferred that the one step portion 5b reduce the width of the flexible board by at least 0.5%. Further, the spacing between the dashed lines at the bending points indicated by points A to D shown in FIGS. 3A to 3D can be set appropriately in accordance with the spacing of the components to be connected and the layout of surrounding components.

In FIGS. 4A to 4C, cut-out portions Sc that narrow the flexible board 1 are formed in both side edges of the board. Here the cut-out portion 5c refers to a portion the shape of which is defined by cutting into a portion of the flexible board 1. The angular portion 5a that bears the bending load in the cut-out portion 5c may be V-shaped portion having an apex or a U-shaped (or arcuate) portion having roundness at the bottom thereof. In FIGS. 4A to 4C, the flexible board 1 has four of the cut-out portions 5c on each side edge, and one pair of mutually opposing cut-out portions 5c is provided with respect to each single bending position. Thus, four pairs of the recessed angular portions 5a are formed. By providing the cut-out portions 5c, the bending load acts upon the locations of the board at which the width thereof is reduced by the cut-out portions 5c and hence the flexible board 1 becomes easy to bend. Accordingly, the cut-out portions 5c are formed in such a manner that the locations (angular portions 5a) of reduced board width will lie at the bending points (points A to D).

For example, in the form of the invention illustrated in FIG. 4A, triangular shaped (V-shaped) cut-out portions Sc are formed on both side edges of the flexible board 1 so as to oppose each other. In the form of the invention illustrated in FIG. 4B, however, arcuate (semi-elliptical, semicircular or U-shaped) cut-out portions 5c having curvature are formed on both side edges of the flexible board 1 so as to oppose each other. In both arrangements, the angular portions 5a are disposed at the bending points (points A to D) so as to reduce the width of the bending positions. However, the angular portion 5a has an apex in the arrangement of FIG. 4A and exhibits roundness in the arrangement of FIG. 4B. Further, in the arrangement of FIG. 4B, the cut-out portions 5c at points B and C are made deeper than those at points A and D to thereby produce a difference in the width of the flexible board 1. In the arrangement of FIG. 4C, constrictions are formed by combining the step portions 5a and the cut-out portions 5c. Further, besides adopting the forms of the invention illustrated in FIGS. 4A to 4C, the cut-out portions 5c may be made a pair of incising lines.

One cut-out portion 5c preferably reduces the width of the flexible board by at least 0.1 mm. For example, in the case of the arrangement shown in FIG. 4A, width d₅ preferably is 0.1 mm or greater and, more preferably, 0.2 mm or greater. In a case where the cut-out portion 5c is expressed by a ratio with respect to the full width of the flexible board 1, it is preferred that the one cut-out portion 5c reduce the width of the flexible board by at least 0.5%. Further, the spacing between the dashed lines at the bending points indicated by points A to D shown in FIGS. 4A to 4C can be set appropriately in accordance with the spacing of the components to be connected and the layout of surrounding components.

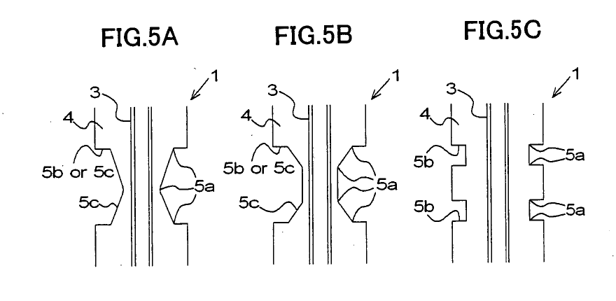

Other forms of the flexible board according to the present invention are illustrated FIGS. 5A to 5C. In FIG. 5A, a constricted portion on each side edge of the flexible board 1 has three recessed angular portions 5a. The constricted portion defines a shape that unites two step portions 5b and one cut-out portion 5c or a shape that unites three cut-out portions 5c. A central angular portion 5a (the portion where the board is narrowest) is rounded. In FIG. 5B, the constricted portion has four recessed angular portions 5a. This constricted portion defines a shape that unites two step portions 5b and two cut-out portions 5c or a shape that unites four cut-out portions 5c. In FIG. 5C, two constricted portions are formed on each side edge of the flexible board 1, and one constricted portion is formed to have two recessed angular portions 5a. This constricted portion defines a shape obtained by combining two mutually facing step portions 5b.

In the forms of the invention illustrated in FIGS. 3A to 5C, a pair of mutually opposing angular portions 5a (step portions 5b or cut-out portions 5c) have line symmetry with respect to the center line of the flexible board 1 along the longitudinal direction. However, the pair of mutually opposing angular portions 5a (step portions 5b or cut-out portions 5c) need not have line symmetry.

In the flexible board 1 of the present invention, various resins can be used appropriately as an insulating layer 4 taking the modulus of elasticity, etc., into consideration. For example, polyimide having a Young's modulus of 5.7 GPa can be used. A metal exhibiting good electrical conductivity preferably is used as the conductor layer 3, and copper foil is particularly desirable. Preferably the flexible board 1 is formed to have a thickness of less than 0.1 mm. The angular portions (step portions and/or cut-out portions) of the flexible board may be formed at the same time that the insulating layer is formed, or the angular portions may be formed by cutting away portions of the insulating layer 4 after the flexible board 1 is fabricated.

### EXAMPLE

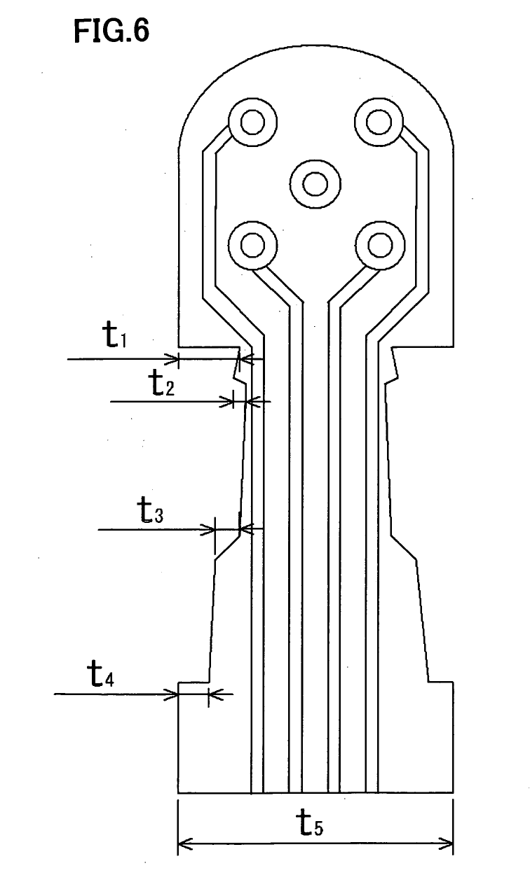

The flexible board 1 illustrated in FIG. 6 was fabricated using copper foil as the conductor layer. A constricted portion has four pairs of recessed angular portions in such a manner that four bending points are provided. The constricted portion was formed from four step portions of maximum widths t₁ of 1.2 mm (approximately 21% of total board width), t₂ of 0.2 mm (approximately 3.6%), t₃ of 0.5 mm (approximately 8.9%) and t₄ of 0.6 mm (approximately 11%) in both side edges of the flexible board the overall width t₅ of which is 5.6 mm in such a manner that the width of the step portion at the central part of the board is the smallest. Each step portion tapers toward the upper side, and the recessed angular portion is situated at the bending position. From another point of view, the constricted portion can be regarded as being formed from four contiguously formed cut-out portions. In order to be incorporated in an optical transceiver of the kind depicted in FIG. 1, this flexible board was first soldered to the transceiving module, after which the flexible board was bent into the configuration illustrated in FIG. 1. As a result, the flexible board could be bent easily and smoothly at the prescribed bending positions (angular portions).

A flexible board according to the present invention can be utilized in various electronic devices such as optical transceivers.

As many apparently widely different embodiments of the present invention can be made without departing from the spirit and scope thereof, it is to be understood that the invention is not limited to the specific embodiments thereof except as defined in the appended claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A flexible board comprising:
an insulating layer exhibiting flexibility;
a conductor layer; and
at least one load-bearing portion that causes bending load to concentrate at one or more bending positions.

2. A flexible board comprising:
an insulating layer exhibiting flexibility;
a conductor layer; and
recessed angular portions situated in both side edges of said flexible board so as to oppose each other;
each side edge of said flexible board having three or more of said angular portions.

3. A flexible board comprising:
an insulating layer exhibiting flexibility;
a conductor layer; and
at least one constricted portion that reduces width of said flexible board;
wherein said constricted portion is situated on both side edges of said flexible board in such a manner that said constricted portions oppose each other, and has at least one of a step portion having a step-like shape and a cut-out portion having a V- or U-like shape;
three or more in total of step-like portions and/or cut-out portions being situated together on each side edge of said flexible board.

4. The flexible board according to claim 1, wherein one step portion or cut-out portion reduces the width of said flexible board by at least 0.1 mm.

5. The flexible board according to claim 2, wherein one step portion or cut-out portion reduces the width of said flexible board by at least 0.1 mm.

6. The flexible board according to claim 3, wherein one step portion or cut-out portion reduces the width of said flexible board by at least 0.1 mm.

7. The flexible board according to claim 1, wherein thickness is not more than 0.1 mm.

8. The flexible board according to claim 2, wherein thickness is not more than 0.1 mm.

9. The flexible board according to claim 3, wherein thickness is not more than 0.1 mm.

10. The flexible board according to claim 1, wherein the insulating layer is polyimide and the conductor layer is copper.

11. The flexible board according to claim 2, wherein the insulating layer is polyimide and the conductor layer is copper.

12. The flexible board according to claim 3, wherein the insulating layer is polyimide and the conductor layer is copper.

13. The flexible board according to claim 1, wherein said at least one load-bearing portion comprises at least one constricted portion that reduces the width of said flexible board by at least 0.5% of the entire width of the flexible board.

14. The flexible board according to claim 2, wherein said recessed angular portions comprise at least one constricted portion that reduces the width of said flexible board by at least 0.5% of the entire width of the flexible board.

15. The flexible board according to claim 3, wherein said at least one constricted portion reduces the width of said flexible board by at least 0.5% of the entire width of the flexible board.

16. An optical transceiver comprising said flexible board according to claim 1.

17. An optical transceiver comprising said flexible board according to claim 2.

18. An optical transceiver comprising said flexible board according to claim 3.
